(19) United States
(12) Patent Application Publication
(10) Pub. No.: US 2019/0157585 A1
(43) Pub. Date: May 23, 2019

(54) FLEXIBLE DISPLAY PANEL, FLEXIBLE DISPLAY APPARATUS AND METHOD OF MANUFACTURING FLEXIBLE DISPLAY PANEL

(71) Applicants: BOE TECHNOLOGY GROUP CO., LTD., Beijing (CN); HEFEI XINSHENG OPTOELECTRONICS TECHNOLOGY CO., LTD., Hefei (CN)

(72) Inventors: Wenbin Jia, Beijing (CN); Xinxin Wang, Beijing (CN); Zhijie Ye, Beijing (CN); Rui Peng, Beijing (CN); Yikun Dou, Beijing (CN); Yue Hu, Beijing (CN); Lifang Song, Beijing (CN); Li Sun, Beijing (CN)

(21) Appl. No.: 15/982,893

(22) Filed: May 17, 2018

(30) Foreign Application Priority Data
Nov. 23, 2017 (CN) 201711179756.7

(51) Int. Cl. H01L 51/00; H01L 27/32; H01L 51/56; B32B 3/26; B32B 27/08; B32B 27/28; B32B 27/32

(52) U.S. Cl. CPC H01L 51/0097; H01L 27/3244; H01L 51/56; H01L 51/003; B32B 3/266; B32B 2457/206; B32B 27/281; B32B 27/32; H01L 2251/5338; H01L 2227/326; B32B 27/08

(57) ABSTRACT

A flexible display panel, a flexible display apparatus and a method of manufacturing the flexible display panel are disclosed. The method includes: forming a flexible substrate on a substrate, the flexible substrate including a first flexible buffer region having a first bending strength and a second flexible buffer region having a second bending strength, and the first bending strength being greater than the second bending strength; and forming display devices in the first flexible buffer region and the second flexible buffer region of the flexible substrate. The flexible display panel includes: a flexible substrate, the flexible substrate including a first flexible buffer region having a first bending strength and a second flexible buffer region having a second bending strength, and the first bending strength being greater than the second bending strength; and display devices disposed in the first flexible buffer region and the second flexible buffer region.

### CROSS-REFERENCE TO RELATED APPLICATION

This application claims the benefit of Chinese Patent Application No. 201711179756.7, filed with the State Intellectual Property Office of China on Nov. 23, 2017, the whole disclosure of which is incorporated herein by reference.

### BACKGROUND

### 1. Technical Field

Embodiments of the present disclosure relate to a flexible display panel, a flexible display apparatus and a method of manufacturing the flexible display panel.

### 2. Description of the Related Art

A conventional method of manufacturing a flexible display panel comprises: adhering a flexible substrate to a rigid substrate, forming an electronic element such as a thin film transistor on the flexible substrate, and separating the flexible substrate from the rigid substrate.

### SUMMARY

Embodiments of the present disclosure provide a method of manufacturing a flexible display panel, comprising:

forming a flexible substrate on a substrate, wherein the flexible substrate comprises a first flexible buffer region having a first bending strength and a second flexible buffer region having a second bending strength, and the first bending strength is greater than the second bending strength; and

forming display devices in the first flexible buffer region and the second flexible buffer region of the flexible substrate.

According to embodiments of the present disclosure, in the method of manufacturing the flexible display panel,

forming the flexible substrate on the substrate comprises:

forming a flexible base layer on the substrate;

forming a first flexible buffer layer in a first region of the flexible base layer; and

forming a second flexible buffer layer in a second region of the flexible base layer,

wherein a region of the flexible substrate corresponding to the first flexible buffer layer is the first flexible buffer region, and another region of the flexible substrate corresponding to the second flexible buffer layer is the second flexible buffer region.

According to embodiments of the present disclosure, in the method of manufacturing the flexible display panel,

forming the flexible substrate on the substrate further comprises:

forming a planarization layer on the first flexible buffer layer and the second flexible buffer layer,

wherein a region of the planarization layer of the flexible substrate corresponding to the first flexible buffer layer is the first flexible buffer region, and another region of the planarization layer of the flexible substrate corresponding to the second flexible buffer layer is the second flexible buffer region.

According to embodiments of the present disclosure, in the method of manufacturing the flexible display panel,

the second flexible buffer layer has a less hardness or bending strength than the first flexible buffer layer.

According to embodiments of the present disclosure, in the method of manufacturing the flexible display panel,

the second flexible buffer layer has a greater flexibility than the first flexible buffer layer.

According to embodiments of the present disclosure, in the method of manufacturing the flexible display panel,

forming the first flexible buffer layer in the first region of the flexible base layer comprises forming the first flexible buffer layer from a polymer having a first degree of polymerization in the first region of the flexible base layer, and

forming the second flexible buffer layer in the second region of the flexible base layer comprises forming the second flexible buffer layer from a polymer having a second degree of polymerization in the second region of the flexible base layer, wherein the second degree of polymerization is greater than the first degree of polymerization.

According to embodiments of the present disclosure, in the method of manufacturing the flexible display panel,

forming the flexible substrate on the substrate comprises:

forming a flexible base layer on the substrate;

forming a first flexible buffer layer from a polymer having a first degree of polymerization in a first region of the flexible base layer; and

forming a second flexible buffer layer from a polymer having a second degree of polymerization in a second region of the flexible base layer, wherein the second degree of polymerization is greater than the first degree of polymerization,

wherein a region of the flexible substrate corresponding to the first flexible buffer layer is the first flexible buffer region, and another region of the flexible substrate corresponding to the second flexible buffer layer is the second flexible buffer region.

According to embodiments of the present disclosure, in the method of manufacturing the flexible display panel,

forming the flexible substrate on the substrate further comprises:

forming a planarization layer on the first flexible buffer layer and the second flexible buffer layer,

wherein a region of the planarization layer of the flexible substrate corresponding to the first flexible buffer layer is the first flexible buffer region, and another region of the planarization layer of the flexible substrate corresponding to the second flexible buffer layer is the second flexible buffer region.

According to embodiments of the present disclosure, in the method of manufacturing the flexible display panel, forming the flexible substrate on the substrate comprises:

forming a flexible base layer on the substrate;

forming a first flexible buffer layer from a polymer having a first degree of polymerization in a first region of the flexible base layer, and forming a second flexible buffer layer from a polymer having a second degree of polymerization in a second region of the flexible base layer, wherein the second degree of polymerization is greater than the first degree of polymerization; and

forming a planarization layer on the first flexible buffer layer and the second flexible buffer layer, wherein the flexible base layer, the first flexible buffer layer, the second flexible buffer layer, and the planarization layer constitute the flexible substrate, and wherein a region of the planarization layer of the flexible substrate corresponding to the first flexible buffer layer is the first flexible buffer region, and another region of the planarization layer of the flexible substrate corresponding to the second flexible buffer layer is the second flexible buffer region.

According to embodiments of the present disclosure, in the method of manufacturing the flexible display panel, forming the first flexible buffer layer from the polymer having the first degree of polymerization in the first region of the flexible base layer, and forming the second flexible buffer layer from the polymer having the second degree of polymerization in the second region of the flexible base layer comprise:

forming a first film from the polymer having the first degree of polymerization on the flexible base layer;

removing a first region of the first film and retaining a second region of the first film, by a first patterning process, to form the first flexible buffer layer;

forming a second film from the polymer having the second degree of polymerization on the substrate after the first patterning process, wherein the second degree of polymerization is greater than the first degree of polymerization; and

removing a first portion of the second film located over the first flexible buffer layer, and retaining a second portion of the second film located in a same layer as the first flexible buffer layer, by a second patterning process, to form the second flexible buffer layer.

According to embodiments of the present disclosure, in the method of manufacturing the flexible display panel, the first film and the second film are photoresist films, and the first patterning process and the second patterning process each comprise a photolithographic process, and a development process.

According to embodiments of the present disclosure, in the method of manufacturing the flexible display panel, at least one of elasticity, flexibility, elongation at break, and tensile strength of the planarization layer is between those of the first flexible buffer layer and the second flexible buffer layer.

According to embodiments of the present disclosure, in the method of manufacturing the flexible display panel, the first degree of polymerization is greater than 200 and less than 300, and the second degree of polymerization is greater than 300 and less than 500.

According to embodiments of the present disclosure, in the method of manufacturing the flexible display panel, forming the display devices in the first flexible buffer region and the second flexible buffer region of the flexible substrate comprises:

forming an active layer and/or a via hole of the display devices in the second flexible buffer region of the flexible substrate.

Embodiments of the present disclosure also provide a flexible display panel comprising:

a flexible substrate, wherein the flexible substrate comprises a first flexible buffer region having a first bending strength and a second flexible buffer region having a second bending strength, and the first bending strength is greater than the second bending strength; and

display devices disposed in the first flexible buffer region and the second flexible buffer region of the flexible substrate.

According to embodiments of the present disclosure, in the flexible display panel, the flexible substrate comprises: a flexible base layer, a first flexible buffer layer of a polymer having a first degree of polymerization, and a second flexible buffer layer of a polymer having a second degree of polymerization, and the second degree of polymerization is greater than the first degree of polymerization;

the first flexible buffer layer is located in a first region of the flexible base layer, and the second flexible buffer layer is located in a second region of the flexible base layer; and

a region of the flexible substrate corresponding to the first flexible buffer layer is the first flexible buffer region, and another region of the flexible substrate corresponding to the second flexible buffer layer is the second flexible buffer region.

According to embodiments of the present disclosure, in the flexible display panel, the flexible substrate comprises: a flexible base layer, a first flexible buffer layer of a polymer having a first degree of polymerization, a second flexible buffer layer of a polymer having a second degree of polymerization, and a planarization layer, and the second degree of polymerization is greater than the first degree of polymerization;

the first flexible buffer layer is located in a first region of the flexible base layer, and the second flexible buffer layer is located in a second region of the flexible base layer; and

a region of the planarization layer of the flexible substrate corresponding to the first flexible buffer layer is the first flexible buffer region, and another region of the planarization layer of the flexible substrate corresponding to the second flexible buffer layer is the second flexible buffer region.

According to embodiments of the present disclosure, in the flexible display panel, the display devices comprise an active layer and/or a via hole located in the second flexible buffer region of the flexible substrate.

Embodiments of the present disclosure further provide a flexible display apparatus comprising:

the above flexible display panel.

### BRIEF DESCRIPTION OF THE DRAWINGS

Advantages and features of the present disclosure will become apparent and more readily appreciated from the following detailed description of the embodiments of the present disclosure, taken in conjunction with the accompanying drawing. The drawings are intended to illustrate the embodiments and shall not be construed to limit the present disclosure. Like reference numerals refer to like elements throughout. In the accompanying drawings:

FIG. 1 is a schematic flow diagram of a method of manufacturing a flexible display panel according to an embodiment of the present disclosure;

FIG. 2 is a schematic flow diagram of another specific method of manufacturing a flexible display panel according to an embodiment of the present disclosure;

FIG. 3 is a schematic flow diagram of a further specific method of manufacturing a flexible display panel according to an embodiment of the present disclosure;

FIG. 4 is a schematic sectional view showing a configuration of a display panel formed after performing a step of a specific method of manufacturing a flexible display panel according to an embodiment of the present disclosure;

FIG. 5 is a schematic sectional view showing a configuration of the display panel formed after performing another step of the specific method of manufacturing the flexible display panel according to the embodiment of the present disclosure;

FIG. 6 is a schematic sectional view showing a configuration of the display panel formed after performing a further step of the specific method of manufacturing the flexible display panel according to the embodiment of the present disclosure;

FIG. 7 is a schematic sectional view showing a configuration of the display panel formed after performing a still another step of the specific method of manufacturing the flexible display panel according to the embodiment of the present disclosure;

FIG. 8 is a schematic sectional view showing a configuration of the display panel formed after performing yet another step of the specific method of manufacturing the flexible display panel according to the embodiment of the present disclosure;

FIG. 9 is a schematic sectional view showing a configuration of the display panel formed after performing a still further step of the specific method of manufacturing the flexible display panel according to the embodiment of the present disclosure;

FIG. 10 is a schematic flow diagram of a specific method of manufacturing a flexible display panel according to an embodiment of the present disclosure;

FIG. 11 is a schematic diagram showing a configuration of a specific flexible display panel according to an embodiment of the present disclosure;

FIG. 12 is a schematic diagram showing a force received by a flexible OLED substrate in a related art; and

FIG. 13 is a schematic diagram showing a force received by a specific flexible display panel according to an embodiment of the present disclosure.

### DETAILED DESCRIPTION OF THE EMBODIMENTS

A flexible display panel, a flexible display apparatus and a method of manufacturing the flexible display panel will be described in detail as below with reference to embodiments of the present disclosure taken in conjunction with the accompanying drawings. Features, structures, or characteristics in one or more embodiments may be combined in any appropriate manners.

With a method of manufacturing a flexible display panel according to an embodiment of the present disclosure, a flexible substrate is formed on a substrate, and the flexible substrate includes two flexible buffer regions having different bending strengths. Electronic elements of the display devices having a lower bending strength are formed in one of the two flexible buffer regions which has a lower bending strength. The one of the two flexible buffer regions which has a lower bending strength is subjected to a lower stress than the other of the two flexible buffer regions which has a higher bending strength, thereby facilitating decrease in a variation of a stress in a region where stress concentration occurs, i.e. the flexible buffer region having the lower bending strength, when bent to be deformed, and thus decreasing a wear.

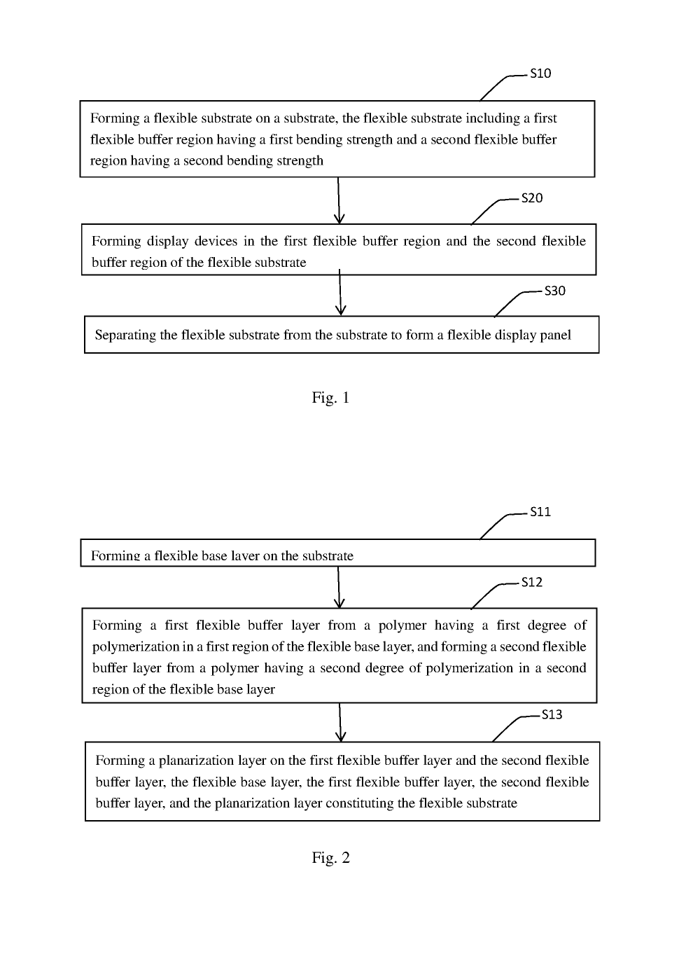

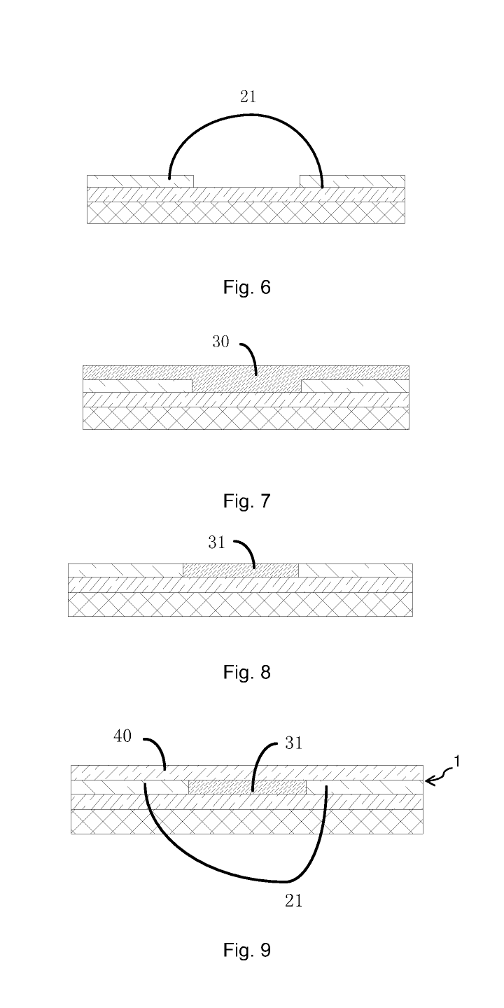

FIG. 1 and FIG. 2 show a method of manufacturing a flexible display panel according to an embodiment of the present disclosure. Referring to FIG. 1, FIG. 2, FIG. 4 to FIG. 9, and FIG. 11, the method of manufacturing the flexible display panel according to the embodiment of the present disclosure includes:

a step S10 of forming a flexible substrate 1 on a substrate 100. The flexible substrate 1 includes a first flexible buffer region 101 having a first bending strength and a second flexible buffer region 102 having a second bending strength, and the first bending strength is greater than the second bending strength, as shown in FIG. 4.

The substrate may be a rigid substrate. The first flexible buffer region and the second flexible buffer region may be located in a same layer on the substrate. The number of each of the first flexible buffer region and the second flexible buffer region is not limited to one, but the number and a position of each of the first flexible buffer region and the second flexible buffer region may be determined according to requirements.

The method further includes a step S20 of forming display devices 1011 and 1012 in the first flexible buffer region 101 and the second flexible buffer region 102 of the flexible substrate 1, respectively.

The display devices 1011 and 1012 may include an electronic element/an electronic structure 1012 having a lower bending strength, and an electronic element/an electronic structure 1011 having a higher bending strength. The electronic element/the electronic structure 1012 having the lower bending strength is/are located in the second flexible buffer region 102, while the electronic element/the electronic structure 1011 having the higher bending strength is/are located in the first flexible buffer region 101.

The method further includes a step S30 of separating the flexible substrate 1 from the substrate 100 to form a flexible display panel.

The flexible substrate is formed on the substrate 100. The flexible substrate includes the first flexible buffer region having the first bending strength and the second flexible buffer region having the second bending strength, and the first bending strength is greater than the second bending strength. The display devices are formed in both the first flexible buffer region and the second flexible buffer region of the flexible substrate 1. The flexible substrate includes the first flexible buffer region having a higher bending strength and the second flexible buffer region having a lower bending strength. When the display devices are formed on the flexible substrate, an electronic element of the display devices having a lower bending strength, and a via hole region and a channel region, in each of which a stress concentration occurs, of the display devices, may be formed in the second flexible buffer region. In the process of bending the flexible display apparatus, the second flexible buffer region having the lower bending strength is subjected to a lower stress than the first flexible buffer region having the higher bending strength, thereby facilitating a decrease in a variation of a stress in the display devices in a region where a stress concentration occurs, i.e. the second flexible buffer region, when bent to be deformed, and thus decreasing a wear. As a result, a probability of occurrence of an abnormal display of a picture displayed by the flexible display apparatus in the process of bending the flexible display apparatus is decreased.

Referring to FIG. 4 to FIG. 9, and FIG. 11, in embodiments of the present disclosure, forming the flexible substrate on the substrate includes: forming a flexible base layer 10 on the substrate 100; forming a first flexible buffer layer in a first region of the flexible base layer 10; and forming a second flexible buffer layer in a second region of the flexible base layer. A region of the flexible substrate corresponding to the first flexible buffer layer is the first flexible buffer region 101, and another region of the flexible substrate corresponding to the second flexible buffer layer is the second flexible buffer region 102.

Referring to FIG. 4 to FIG. 9, and FIG. 11, in embodiments of the present disclosure, forming the flexible substrate on the substrate further includes: forming a planarization layer on the first flexible buffer layer and the second flexible buffer layer. A region of the planarization layer of the flexible substrate corresponding to the first flexible buffer layer is the first flexible buffer region 101, and another region of the planarization layer of the flexible substrate corresponding to the second flexible buffer layer is the second flexible buffer region 102. For example, the second flexible buffer layer has a less hardness or bending strength than the first flexible buffer layer, or the second flexible buffer layer has a greater flexibility than the first flexible buffer layer.

Referring to FIG. 4 to FIG. 9, and FIG. 11, in embodiments of the present disclosure, forming the first flexible buffer layer in the first region of the flexible base layer includes forming the first flexible buffer layer from a polymer having a first degree of polymerization in the first region of the flexible base layer, and forming the second flexible buffer layer in the second region of the flexible base layer includes forming the second flexible buffer layer from a polymer having a second degree of polymerization in the second region of the flexible base layer. The second degree of polymerization is greater than the first degree of polymerization.

Referring to FIG. 4 to FIG. 9, and FIG. 11, in embodiments of the present disclosure, forming the flexible substrate on the substrate includes: forming a flexible base layer 10 on the substrate 100; forming a first flexible buffer layer from a polymer having a first degree of polymerization in a first region of the flexible base layer; and forming a second flexible buffer layer from a polymer having a second degree of polymerization in a second region of the flexible base layer. The second degree of polymerization is greater than the first degree of polymerization. A region of the flexible substrate corresponding to the first flexible buffer layer is the first flexible buffer region 101, and another region of the flexible substrate corresponding to the second flexible buffer layer is the second flexible buffer region 102.

Referring to FIG. 4 to FIG. 9, and FIG. 11, in embodiments of the present disclosure, forming the flexible substrate on the substrate further includes: forming a planarization layer on both the first flexible buffer layer and the second flexible buffer layer. A region of the planarization layer of the flexible substrate corresponding to the first flexible buffer layer is the first flexible buffer region, and another region of the planarization layer of the flexible substrate corresponding to the second flexible buffer layer is the second flexible buffer region.

In an example, referring to FIG. 4 to FIG. 9, and FIG. 11, the step S10 includes:

a step S11 of forming a flexible base layer 10 on the substrate 100.

The flexible base layer may be formed from material such as resin, polyimide (PI) or polyethylene (PE) on the substrate by vacuum cooling and drying.

The step S10 further includes a step S12 of forming a first flexible buffer layer from a polymer having a first degree of polymerization in a first region of the flexible base layer, and forming a second flexible buffer layer from a polymer having a second degree of polymerization in a second region of the flexible base layer. The second degree of polymerization is greater than the first degree of polymerization.

The first flexible buffer layer and the second flexible buffer layer may be both formed from material such as resin, polyimide (PI) or polyethylene (PE). The first degree of polymerization is greater than 200 and less than 300, and the second degree of polymerization is greater than 300 and less than 500. An average molecular weight of the polymer of the first flexible buffer layer is in the range of 10000-20000, and an average molecular weight of the polymer of the second flexible buffer layer is in the range of 20000-25000.

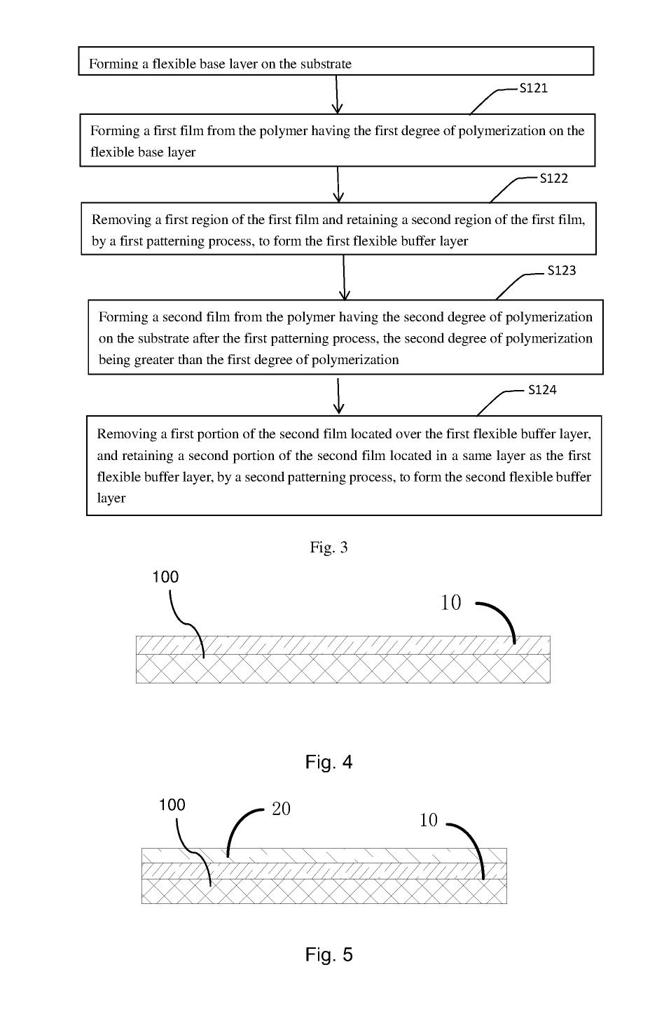

Referring to FIG. 3 to FIG. 8, as an example, the step S12 includes:

a step S121 of forming a first film 20 from the polymer having the first degree of polymerization on the flexible base layer 10.

Specifically, the first film may be formed from photoresist. The first film may be a photoresist film, but is not limited to that herein.

The step S12 further includes a step S122 of removing a first region of the first film and retaining a second region of the first film, by a first patterning process, to form the first flexible buffer layer 21.

The first patterning process needs to be selected according to specific material of the first film. In the case where the first film is formed from photoresist, the first patterning process may specifically include a photolithographic process, and a development process.

The step S12 further includes a step S123 of forming a second film 30 from the polymer having the second degree of polymerization on the substrate after the first patterning process. The second degree of polymerization is greater than the first degree of polymerization.

Specifically, the second film may be formed from photoresist. The second film may be a photoresist film, but is not limited to that herein.

The step S12 further includes a step S124 of removing a first portion of the second film located over the first flexible buffer layer, and retaining a second portion of the second film located in a same layer as the first flexible buffer layer, by a second patterning process, to form the second flexible buffer layer 31.

The second patterning process needs to be selected according to specific material of the second film. In the case where the second film is formed of photoresist, the second patterning process may specifically include a photolithographic process, and a development process. A method including the photolithographic process and the development process is simpler than a method including a chemical vapor deposition (CVD).

Specific steps included by the step S12 are not limited to the above steps. As another example, the step S12 includes:

forming a second film from the polymer having the second degree of polymerization on the flexible base layer.

Specifically, the second film may be formed of photoresist. The second film may be a photoresist film, but is not limited to that herein.

The step S12 further includes: removing a first region of the second film and retaining a second region of the second film, by a third patterning process, to form the second flexible buffer layer.

The third patterning process needs to be selected according to specific material of the second film. In the case where the second film is formed of photoresist, the third patterning process may specifically include a photolithographic process, and a development process.

The step S12 further includes: forming a first film from the polymer having the first degree of polymerization on the substrate after the third patterning process. The second degree of polymerization is greater than the first degree of polymerization.

Specifically, the first film may be formed of photoresist. The first film may be a photoresist film, but is not limited to that herein.

The step S12 further includes: removing a first portion of the first film located over the second flexible buffer layer, and retaining a second portion of the first film located in a same layer as the second flexible buffer layer, by a fourth patterning process, to form the first flexible buffer layer.

The fourth patterning process needs to be selected according to specific material of the first film. In the case where the first film is formed from photoresist, the fourth patterning process may specifically include a photolithographic process, and a development process.

As shown in FIG. 2 and FIG. 9, the step S10 further includes a step S13 of forming a planarization layer 40 on both the first flexible buffer layer 21 and the second flexible buffer layer 31. The flexible base layer, the first flexible buffer layer, the second flexible buffer layer, and the planarization layer constitute the flexible substrate. A region of the planarization layer of the flexible substrate corresponding to the first flexible buffer layer is the first flexible buffer region, and another region of the planarization layer of the flexible substrate corresponding to the second flexible buffer layer is the second flexible buffer region.

A flexibility of the planarization layer is between a flexibility of the first flexible buffer layer and a flexibility of the second flexible buffer layer. Specifically, at least one of elasticity, flexibility, elongation at break, and tensile strength of the planarization layer is between those of the first flexible buffer layer and the second flexible buffer layer. A flexibility of the planarization layer is between a flexibility of the first flexible buffer layer and a flexibility of the second flexible buffer layer, thereby facilitating release of a stress of the display devices having a lower bending strength which correspond to the second flexible buffer layer.

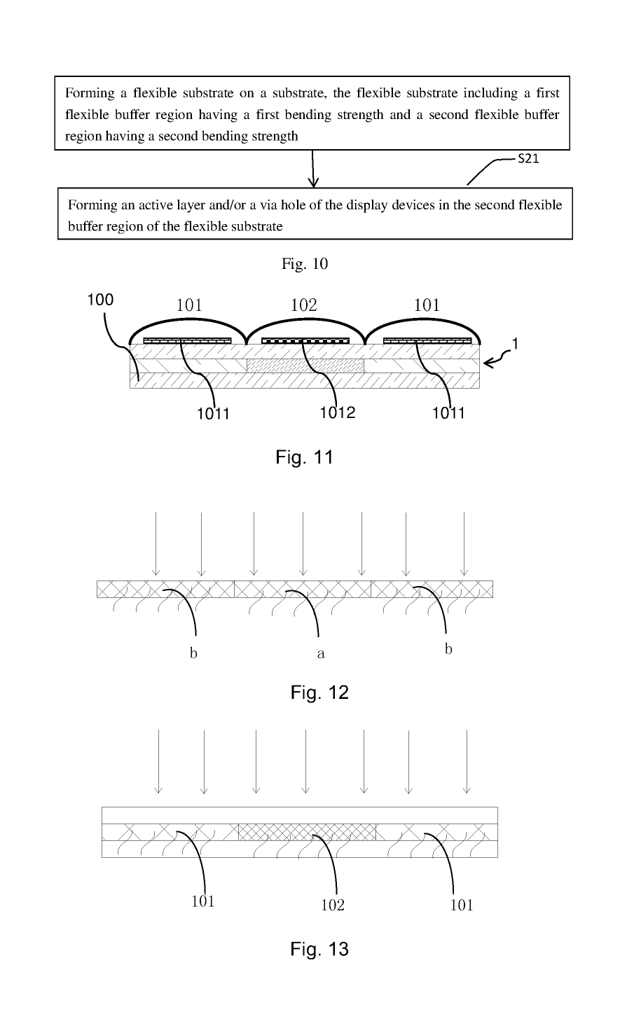

As shown in FIG. 10 and FIG. 11, the step S20 may include:

a step S21 of forming display devices 1011 and 1012 in the first flexible buffer region 101 and the second flexible buffer region 102 of the flexible substrate 1. Forming the display devices in the first flexible buffer region and the second flexible buffer region of the flexible substrate 1 may include:

forming an active layer and/or a via hole 1012 of the display devices in the second flexible buffer region 102 of the flexible substrate.

Generally, the electronic element/the electronic structure 1012 having the lower bending strength include the active layer and the via hole 1012, but the electronic element/the electronic structure 1012 having the lower bending strength are not limited to the active layer and the via hole 1012. The electronic element/the electronic structure 1012 having the lower bending strength may be formed in the second flexible buffer region 102. The second flexible buffer region having the lower bending strength is subjected to a lower stress than the first flexible buffer region having the higher bending strength, thereby facilitating a decrease in a variation of a stress in the display devices in a region where a stress concentration occurs, i.e. the second flexible buffer region, when bent to be deformed, and thus decreasing wear.

Based on the same inventive concept, embodiments of the present disclosure also provide a flexible display panel including the flexible substrate. The flexible substrate includes two flexible buffer regions having different bending strengths. Electronic elements of the display devices having a lower bending strength may be formed in one of the two flexible buffer regions which has a lower bending strength. The one of the two flexible buffer regions which has the lower bending strength is subjected to a lower stress than the other of the two flexible buffer regions which has a higher bending strength, thereby facilitating a decrease in a variation of a stress in the display devices in a region where a stress concentration occurs, when bent to be deformed, and thus decreasing wear.

FIG. 11 shows a flexible display panel according to an embodiment of the present disclosure. The flexible display panel may be manufactured by the above manufacturing method. Referring to FIG. 11, the flexible display panel according to an embodiment of the present disclosure includes: a flexible substrate 1 and display devices 1011 and 1012.

The flexible substrate 1 includes a first flexible buffer region 101 having a first bending strength and a second flexible buffer region 102 having a second bending strength, and the first bending strength is greater than the second bending strength. The display devices 1011 and 1012 are disposed in the first flexible buffer region 101 and the second flexible buffer region 102 of the flexible substrate 1 respectively.

The display devices 1011 and 1012 may include an electronic element/an electronic structure 1012 having a lower bending strength, and an electronic element/an electronic structure 1011 having a higher bending strength. The electronic element/the electronic structure 1012 having the lower bending strength is/are located in the second flexible buffer region 102, while the electronic element/the electronic structure 1011 having the higher bending strength is/are located in the first flexible buffer region 101. For example, specifically, the display devices include an active layer and/or a via hole located in the second flexible buffer region of the flexible substrate.

The flexible display panel according to the embodiment of the present disclosure includes a flexible substrate. The flexible substrate includes a first flexible buffer region having a first bending strength and a second flexible buffer region having a second bending strength, and the first bending strength is greater than the second bending strength. An electronic element of display devices having a lower bending strength, and a via hole region and a channel region, in each of which a stress concentration occurs, may be formed in the second flexible buffer region. The second flexible buffer region having the lower bending strength is subjected to a lower stress than the first flexible buffer region having the higher bending strength, thereby facilitating a decrease in a variation of stress in the display devices in a region where stress concentration occurs, i.e. the second flexible buffer region, when bent to be deformed, and thus decreasing wear. As a result, a probability of occurrence of an abnormal display of a picture displayed by the flexible display panel in the process of bending the flexible display panel is decreased.

According to an example of the present disclosure, the flexible substrate includes: a flexible base layer, a first flexible buffer layer of a polymer having a first degree of polymerization, and a second flexible buffer layer of a polymer having a second degree of polymerization, and the second degree of polymerization is greater than the first degree of polymerization; the first flexible buffer layer is located in a first region of the flexible base layer, and the second flexible buffer layer is located in a second region of the flexible base layer; and a region of the flexible substrate corresponding to the first flexible buffer layer is the first flexible buffer region, and another region of the flexible substrate corresponding to the second flexible buffer layer is the second flexible buffer region.

According to another example of the present disclosure, the flexible substrate includes: a flexible base layer, a first flexible buffer layer of a polymer having a first degree of polymerization, a second flexible buffer layer of a polymer having a second degree of polymerization, and a planarization layer, and the second degree of polymerization is greater than the first degree of polymerization; the first flexible buffer layer is located in a first region of the flexible base layer, and the second flexible buffer layer is located in a second region of the flexible base layer; and a region of the planarization layer of the flexible substrate corresponding to the first flexible buffer layer is the first flexible buffer region, and another region of the planarization layer of the flexible substrate corresponding to the second flexible buffer layer is the second flexible buffer region.

Based on the same inventive concept, embodiments of the present disclosure also provide a flexible display apparatus including the flexible substrate. The flexible substrate includes two flexible buffer regions having different bending strengths. Electronic elements of display devices having a lower bending strength may be formed in one of the two flexible buffer regions which has a lower bending strength. The one of the two flexible buffer regions which has the lower bending strength is subjected to a lower stress than the other of the two flexible buffer regions which has a higher bending strength, thereby facilitating a decrease in a variation of a stress in the display devices in a region where a stress concentration occurs, when bent to be deformed, and thus decreasing a wear.

The flexible display apparatus according to an embodiment of the present disclosure includes: a flexible display panel. The flexible display panel includes a flexible substrate and display devices.

The flexible substrate includes a first flexible buffer region having a first bending strength and a second flexible buffer region having a second bending strength, and the first bending strength is greater than the second bending strength; and the display devices are disposed in the first flexible buffer region and the second flexible buffer region of the flexible substrate.

The display devices 1011 and 1012 may include an electronic element/an electronic structure 1012 having a lower bending strength, and an electronic element/an electronic structure 1011 having a higher bending strength. The electronic element/the electronic structure 1012 having the lower bending strength is/are located in the second flexible buffer region 102, while the electronic element/the electronic structure 1011 having the higher bending strength is/are located in the first flexible buffer region 101. For example, specifically, the display devices include an active layer and/or a via hole located in the second flexible buffer region of the flexible substrate.

The flexible display apparatus according to the embodiments of the present disclosure may include any products or parts having a display function such as an electronic paper, a mobile phone, a tablet computer, a TV, a display, a notebook computer, a digital frame, and navigator. The electronic element/the electronic structure having the lower bending strength can be effectively protected. When the second flexible buffer region where a stress concentration occurs is subjected to a stress, the second flexible buffer region is subjected to a lower stress than the first flexible buffer region, so that the stress of the second flexible buffer region is reduced, thereby decreasing a wear.

Specifically, the flexible display panel according to the above embodiments may be used directly as the flexible display panel described in the present embodiment. The relevant contents in the above embodiments may be referred to for a specific structure of the flexible display panel described in the present embodiment, and thus the specific structure of the flexible display panel described in the present embodiment is no longer described for the sake of brevity.

In order to facilitate understanding of the embodiments of the present disclosure, as shown in FIG. 12, in a flexible OLED substrate in a related art, a via hole and an active region are located in a region a, and are not located in a region b. When the flexible OLED substrate receives a force to be bent, the region (such as the via hole and the active region) where a stress concentration occurs is subjected to a higher stress and thus is vulnerable to damage. In the embodiments of the present disclosure, however, as shown in FIG. 13, the electronic elements of the display devices having a lower bending strength may be formed in the second flexible buffer region 102 which has a lower bending strength. The second flexible buffer region 102 having the lower bending strength is subjected to a lower stress than the first flexible buffer region 101 having the higher bending strength, thereby facilitating decrease in a variation of a stress in the display devices in a region where a stress concentration occurs, i.e. the second flexible buffer region, when bent to be deformed, and thus decreasing wear.

In the above embodiments, the planarization layer has been disclosed. However, the planarization layer may be replaced with any other layer of the display panel so that it is not necessary to provide a special planarization layer.

In the foregoing embodiments, the description of each embodiment has its own emphasis. For the part that is not described in detail in an embodiment, reference may be made to the relevant description of other embodiments.

In the description, numerous specific details are set forth. It can be understood, however, that the embodiments of the present disclosure may be practiced without these specific details. In some embodiments, well-known structures and techniques have not been shown and described in detail in order not to obscure the understanding of the description.

Apparently, various changes and modifications to the present disclosure may be made by those skilled in the art without departing from the spirit and scope of the disclosure. Therefore, if these amendments and modifications to the present disclosure belong to the scope defined in the appended claims of the present disclosure and their equivalents, the present disclosure is intended to include the changes and modifications.

What is claimed is:

1. A method of manufacturing a flexible display panel, comprising:
forming a flexible substrate on a substrate, wherein the flexible substrate comprises a first flexible buffer region having a first bending strength and a second flexible buffer region having a second bending strength, and the first bending strength is greater than the second bending strength; and
forming display devices in the first flexible buffer region and the second flexible buffer region of the flexible substrate.

2. The method of claim 1, wherein forming the flexible substrate on the substrate comprises:
forming a flexible base layer on the substrate;
forming a first flexible buffer layer in a first region of the flexible base layer; and
forming a second flexible buffer layer in a second region of the flexible base layer,
wherein a region of the flexible substrate corresponding to the first flexible buffer layer is the first flexible buffer region, and another region of the flexible substrate corresponding to the second flexible buffer layer is the second flexible buffer region.

3. The method of claim 1, wherein forming the flexible substrate on the substrate further comprises:
forming a planarization layer on the first flexible buffer layer and the second flexible buffer layer,
wherein a region of the planarization layer of the flexible substrate corresponding to the first flexible buffer layer is the first flexible buffer region, and another region of the planarization layer of the flexible substrate corresponding to the second flexible buffer layer is the second flexible buffer region.

4. The method of claim 2, wherein:
the second flexible buffer layer has a lesser hardness or bending strength than the first flexible buffer layer.

5. The method of claim 2, wherein:
the second flexible buffer layer has a greater flexibility than the first flexible buffer layer.

6. The method of claim 2, wherein:
forming the first flexible buffer layer in the first region of the flexible base layer comprises forming the first flexible buffer layer from a polymer having a first degree of polymerization in the first region of the flexible base layer, and
forming the second flexible buffer layer in the second region of the flexible base layer comprises forming the second flexible buffer layer from a polymer having a second degree of polymerization in the second region of the flexible base layer, wherein the second degree of polymerization is greater than the first degree of polymerization.

7. The method of claim 1, wherein forming the flexible substrate on the substrate comprises:
forming a flexible base layer on the substrate;
forming a first flexible buffer layer from a polymer having a first degree of polymerization in a first region of the flexible base layer; and
forming a second flexible buffer layer from a polymer having a second degree of polymerization in a second region of the flexible base layer, wherein the second degree of polymerization is greater than the first degree of polymerization,
wherein a region of the flexible substrate corresponding to the first flexible buffer layer is the first flexible buffer region, and another region of the flexible substrate corresponding to the second flexible buffer layer is the second flexible buffer region.

8. The method of claim 7, wherein:
forming the flexible substrate on the substrate further comprises:
forming a planarization layer on the first flexible buffer layer and the second flexible buffer layer,
wherein a region of the planarization layer of the flexible substrate corresponding to the first flexible buffer layer is the first flexible buffer region, and another region of the planarization layer of the flexible substrate corresponding to the second flexible buffer layer is the second flexible buffer region.

9. The method of claim 1, wherein forming the flexible substrate on the substrate comprises:
forming a flexible base layer on the substrate;
forming a first flexible buffer layer from a polymer having a first degree of polymerization in a first region of the flexible base layer, and forming a second flexible buffer layer from a polymer having a second degree of polymerization in a second region of the flexible base layer, wherein the second degree of polymerization is greater than the first degree of polymerization; and
forming a planarization layer on the first flexible buffer layer and the second flexible buffer layer, wherein the flexible base layer, the first flexible buffer layer, the second flexible buffer layer, and the planarization layer constitute the flexible substrate, and wherein a region of the planarization layer of the flexible substrate corresponding to the first flexible buffer layer is the first flexible buffer region, and another region of the planarization layer of the flexible substrate corresponding to the second flexible buffer layer is the second flexible buffer region.

10. The method of claim 9, wherein forming the first flexible buffer layer from the polymer having the first degree of polymerization in the first region of the flexible base layer, and forming the second flexible buffer layer from the polymer having the second degree of polymerization in the second region of the flexible base layer comprise:
forming a first film from the polymer having the first degree of polymerization on the flexible base layer;
removing a first region of the first film and retaining a second region of the first film, by a first patterning process, to form the first flexible buffer layer;
forming a second film from the polymer having the second degree of polymerization on the substrate after the first patterning process, wherein the second degree of polymerization is greater than the first degree of polymerization; and
removing a first portion of the second film located over the first flexible buffer layer, and retaining a second portion of the second film located in a same layer as the first flexible buffer layer, by a second patterning process, to form the second flexible buffer layer.

11. The method of claim 9, wherein:
the first film and the second film are photoresist films, and the first patterning process and the second patterning process each comprise a photolithographic process and a development process.

12. The method of claim 3, wherein:
a flexibility of the planarization layer is between a flexibility of the first flexible buffer layer and a flexibility of the second flexible buffer layer.

13. The method of claim 6, wherein:
the first degree of polymerization is greater than 200 and less than 300, and the second degree of polymerization is greater than 300 and less than 500.

14. The method of claim 1, wherein forming the display devices in the first flexible buffer region and the second flexible buffer region of the flexible substrate comprises:
forming an active layer and/or a via hole of the display devices in the second flexible buffer region of the flexible substrate.

15. A flexible display panel comprising:
a flexible substrate, wherein the flexible substrate comprises a first flexible buffer region having a first bending strength and a second flexible buffer region having a second bending strength, and the first bending strength is greater than the second bending strength; and
display devices disposed in the first flexible buffer region and the second flexible buffer region of the flexible substrate.

16. The flexible display panel of claim 15, wherein:
the flexible substrate comprises a flexible base layer, a first flexible buffer layer of a polymer having a first degree of polymerization, and a second flexible buffer layer of a polymer having a second degree of polymerization, wherein the second degree of polymerization is greater than the first degree of polymerization;
the first flexible buffer layer is located in a first region of the flexible base layer, and the second flexible buffer layer is located in a second region of the flexible base layer; and
a region of the flexible substrate corresponding to the first flexible buffer layer is the first flexible buffer region, and another region of the flexible substrate corresponding to the second flexible buffer layer is the second flexible buffer region.

17. The flexible display panel of claim 15, wherein:
the flexible substrate comprises a flexible base layer, a first flexible buffer layer of a polymer having a first degree of polymerization, a second flexible buffer layer of a polymer having a second degree of polymerization, and a planarization layer, wherein the second degree of polymerization is greater than the first degree of polymerization;
the first flexible buffer layer is located in a first region of the flexible base layer, and the second flexible buffer layer is located in a second region of the flexible base layer; and
a region of the planarization layer of the flexible substrate corresponding to the first flexible buffer layer is the first flexible buffer region, and another region of the planarization layer of the flexible substrate corresponding to the second flexible buffer layer is the second flexible buffer region.

18. The flexible display panel of claim 15, wherein:
the display devices comprise an active layer and/or a via hole located in the second flexible buffer region of the flexible substrate.

19. A flexible display panel comprising:
a flexible substrate, wherein the flexible substrate comprises a first flexible buffer region having a first bending strength and a second flexible buffer region having a second bending strength, and the first bending strength is greater than the second bending strength; and
display devices disposed in the first flexible buffer region and the second flexible buffer region of the flexible substrate,
wherein the flexible display panel is manufactured according to the method of claim 1.

20. A flexible display apparatus comprising:
the flexible display panel according to claim 15.
